(19) United States
(12) Patent Application Publication
(10) Pub. No.: US 2024/0345161 A1
(43) Pub. Date: Oct. 17, 2024

(54) Machine Learning Control of Clock Drift

(71) Applicants: Richard Maiden, El Dorado, CA (US); Ankur Vora, Sunnyvale, CA (US); Hans Brandberg, Skarpnack (SE); Kishan Shenoi, Saratoga, CA (US)

(72) Inventors: Richard Maiden, El Dorado, CA (US); Ankur Vora, Sunnyvale, CA (US); Hans Brandberg, Skarpnack (SE); Kishan Shenoi, Saratoga, CA (US)

(21) Appl. No.: 18/756,925

(22) Filed: Jun. 27, 2024

(51) Int. Cl. G01R 31/317; H03L 7/08

(52) U.S. Cl. CPC G01R 31/31727; H03L 7/08

(57) ABSTRACT

Systems and methods for controlling clock drift of an integrated circuit device are provided. Such a system may include a local oscillator to provide a reference clock signal, a phase-locked loop to provide a system clock signal based on the reference clock signal and a drift control signal, and processing circuitry to generate the drift control signal. In a synchronization mode, the processing circuitry may generate the drift control signal based on an input time reference signal. In a holdover mode, the processing circuitry may generate the drift control signal based on a trained machine learning model.

### BACKGROUND

This disclosure relates generally to controlling clock drift of a system clock of an integrated circuit (IC) device such as a processor, application specific integrated circuit (ASIC), or programmable logic device (PLD) such as a field programmable gate array (FPGA).

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuits are ubiquitous in modern electronics. Integrated circuits often perform operations that depend on accurate timing and synchronization with other integrated circuits. Synchronization may be achieved using a remote time input signal that is based on a remote time source. For example, a global navigation satellite system (GNSS) such as the Global Positioning System (GPS) may provide a 1 pulse per second (1PPS) signal or IEEE1588 Precision Time Protocol (PTP) may provide a PTP signal that accurately and precisely provide a remote input time signal from a common remote time source, such as a reference clock of the U.S. National Institute of Standards and Technology (NIST). These systems allow software or hardware of the integrated circuit device to determine a difference (error) between the local sense of time at the device and the actual time that is received from a PTP Grand Master or GNSS. The calculated correction is applied as a clock drift control signal that adjusts the behavior of frequency or phase control circuitry, such as a phase-locked loop (PLL), to instruct the local clock run faster or slower.

This keeps the local clock signal of the integrated circuit device synchronized when a remote time input signal is available. There are situations, however, where these signals may become unavailable. This is the “holdover” condition. Under this condition, the local clock will drift based on the inaccuracies of the components of the integrated circuit device (principally the local oscillator (LO) and phase-locked loop (PLL) circuitry). A common solution to the holdover problem is to use a local oscillator that shows very little variation with respect to the different factors affecting frequency drift. Such devices are very costly. There are other solutions where electronic circuitry is embedded in the oscillator which tries to compensate for the behavior of the crystal. These devices also tend to be very expensive and power hungry. Some local oscillator manufacturers provide a physics-based model (e.g., table or equation) to represent how a given part number is expected to age or drift over time based on some testing. This allows for a coarse estimation of the amount of clock drift that is likely to be experienced for holdover conditions when the remote time input signal is available. Yet this coarse estimation may not accurately estimate the clock drift under many conditions when parameters of the integrated circuit device are different than those assumed by the manufacturer providing the physics-based model. As such, the system clock may experience significant amounts of drift using these techniques.

### BRIEF DESCRIPTION OF THE DRAWINGS

Various aspects of this disclosure may be better understood upon reading the following detailed description and upon reference to the drawings in which:

FIG. 1 is a block diagram of an integrated circuit system to control clock drift of an integrated circuit device by training a machine learning model based on a set of device parameters and a remote input time signal;

FIG. 2 is the block diagram of the integrated circuit system being used to control the clock drift of the integrated circuit device using the trained machine learning model based on the set of device parameters;

FIG. 3 is a flowchart of a method for using the integrated circuit system to the control clock drift of the integrated circuit device;

FIG. 4 is a flowchart of a method for training the machine learning model; and

FIG. 5 is a block diagram of a data processing system incorporating the integrated circuit system.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

This disclosure relates to systems and methods to control clock drift using a trained machine learning model. As mentioned above, a local system clock may be synchronized with a common remote time source using a remote time input signal that is based on the remote time source. Examples include a 1 pulse per second (1PPS) signal from a global navigation satellite system (GNSS) such as the Global Positioning System (GPS) or an IEEE1588 Precision Time Protocol (PTP) signal. When these signals are available, the local system clock may operate in a synchronization mode, where processing circuitry may control the clock drift that naturally occurs by adjusting clock frequency or phase control circuitry (e.g., phase-locked loop (PLL) circuitry) to speed up or slow down to match the remote time source.

When the remote time input signals are unavailable, the local system clock may begin to drift in relation to the remote time source. Under these conditions, the local system clock may operate in a holdover mode, where processing circuitry may generate the drift control signal without the remote time input signals. Rather than rely exclusively on a physics-based model, which may not fully account for the behavior of the components of the local system clock under the present conditions, the clock drift control signal may be generated using a trained machine learning model. The machine learning model may be trained during manufacturing before normal operation or in the field during normal operation. The machine learning model may be any suitable artificial intelligence system that is trained using training data that includes the drift control signal that is properly determined based on a remote time input signal and a set of parameters of the integrated circuit device. The set of parameters of the integrated circuit device may be any suitable determinable (e.g., measurable, estimable, recorded) aspect(s) of the integrated circuit device at the time that the drift control signal is properly determined based on a remote time input signal. The set of parameters may include, without limitation, a present temperature of the integrated circuit device, a present supply voltage of the integrated circuit device, an age of a local oscillator of the integrated circuit device, an age of the frequency or phase control circuitry (e.g., PLL), a powered-on time of the integrated circuit device since the last power-on, a lifetime powered-on time of the integrated circuit device representing the sum of all powered-on time during the lifetime of the integrated device, or anything that may be measured by sensors in or around the integrated circuit device, such as a geographic location, a motion of the integrated circuit device, or an altitude of the integrated circuit device, or any suitable combination of these.

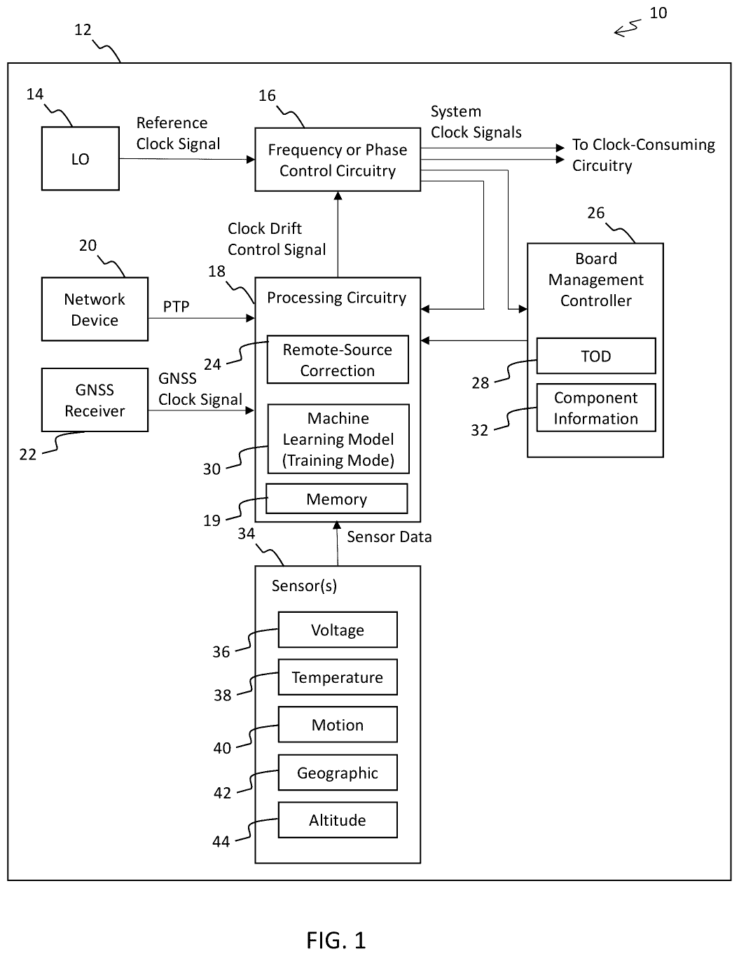

FIG. 1 illustrates a block diagram of a clock drift control system 10 to keep local system clock signals of an integrated circuit device 12 synchronized with a remote time source, such as a reference clock of the U.S. National Institute of Standards and Technology (NIST). The integrated circuit device 12 may represent any suitable integrated circuit device that uses a system clock signal to perform operations. The integrated circuit device 12 may include a processor, an application specific integrated circuit (ASIC), a programmable logic device (PLD) such as a field programmable gate array (FPGA), a memory device, a networking device, a digital signal processing (DSP) device, or any other suitable integrated circuitry. Moreover, the integrated circuit device 12 may represent a single monolithic integrated circuit or may include multiple integrated circuits in a single package or multiple packages.

To generate system clock signals that are consumed by clock-consuming circuitry of the integrated circuit device 12, a local oscillator (LO) 14 may generate a reference clock signal when applied with a supply voltage. The LO 14 may take any suitable form. Indeed, there are many different kinds of LOs whose cost may vary dramatically. LOs in wireless systems are often either oven-controlled crystal oscillators (OCXOs) or temperature-controlled crystal oscillators (TCXOs). As will be discussed further below, because the clock drift control system 10 of this disclosure may use a trained machine learning model to accurately and precisely control clock drift, the LO 14 may be comparatively less accurate and may therefore be less costly. The LO 14 sends the reference clock signal to frequency or phase control circuitry 16, which may include any suitable circuitry to generate a system clock signal, such as a phase-locked loop (PLL) or delay-locked loop (DLL). The frequency or phase control circuitry 16 receives the reference clock signal from the LO 14. The frequency or phase control circuitry 16 also receives a clock drift control signal (e.g., a digitally controlled oscillator (DCO) control signal, a voltage controlled oscillator (VCO) voltage signal) from processing circuitry 18 that may execute instructions stored on memory 19 (e.g., volatile or non-volatile memory) to generate the clock drift control signal. In some embodiments, the instructions may be part of the Intel® FPGA Advanced Servo software. For embodiments in which the clock drift control signal is an analog signal, the processing circuitry 18 may provide the signal to suitable digital-to-analog (DAC) circuitry. The processing circuitry 18 may represent any suitable data processing system that may include a processor (e.g., a Reduced Instruction Set Computer (RISC) processor such as an Advanced RISC Machine processor, an x86 such as an Intel® Xeon®, Intel® Core i3, Intel® Core i5, Intel® Core i7, or Intel® Core i9 processor by Intel Corporation) Additionally or alternatively, the processing circuitry 18 may be implemented in programmable logic circuitry or application-specific integrated circuitry. Based on the clock drift control signal, frequency or phase control circuitry 16 increases or decreases the frequency of the system clock signals in relation to the reference clock signal from the LO 14. In this way, the clock drift control signal may enable the system clock signals to remain synchronized even when the reference clock signal from the LO 14 varies over time.

The processing circuitry 18 may generate the clock drift control signal in different ways depending on whether a remote input time signal (e.g., a 1 pulse per second (1PPS) signal or IEEE1588 Precision Time Protocol (PTP) signal) is available. Indeed, a PTP signal may be received from a network source via a network device 20. The network device 20 may include any suitable networking circuitry to access other devices. The network device 20 may include networking circuitry to access a local area network such as Ethernet or an 802.11x Wi-Fi network, or a wide area network such as a 4G, Long-Term Evolution (LTE), or 5G cellular network. A 1PPS may be received from a Global Navigation Satellite System (GNSS) receiver 22, which may be included in the integrated circuit device 12 or may be separate from the integrated circuit device 12 but in communication with the integrated circuit device 12.

When a remote input time signal, such as a 1PPS signal or PTP signal, is available, the processing circuitry 18 may operate in a synchronization mode. The processing circuitry 18 may perform a remote-source correction 24 using software and/or specialized hardware to generate the clock drift control signal based on the remote input time signal. The remote-source correction 24 may represent any suitable technique to generate the clock drift control signal based on the remote input time signal. Under normal operation in synchronization mode, the remote-source correction 24 determines whether the frequency or phase control circuitry 16 (e.g., PLL) should run faster or slower. In many cases, adjustments are made one to several times per second and the frequency or phase control circuitry 16 is instructed to run of the order fractions of one part in a billion faster or slower.

For example, a board management controller 26 may maintain a time of day (TOD) register 28 that, based on a count of the system clock signals, records the current date and time. The remote-source correction 24 may generate the clock drift control signal based on a difference between the current TOD register 28 and the remote input time signal (e.g., PTP signal, 1PPS signal). Additionally or alternatively, the remote-source correction 24 may maintain a separate count of the system clock signals. In any event, while the remote-source correction 24 accurately maintains timing accuracy while the remote input time signals are available, there may be times when the remote input time signals are unavailable.

When a remote input time signal, such as a 1PPS signal or PTP signal, is unavailable, the processing circuitry 18 may operate in a holdover mode. To prepare for the holdover mode, the clock drift control system 10 may use any suitable set of parameters of the integrated circuit device 12 to train a machine learning model 30 during the synchronization mode during normal operation. Additionally or alternatively, the machine learning model 30 may be trained during the manufacturing process (e.g., performed by a supplier or during a factory batch test mode). The machine learning model 30 may represent any suitable machine learning model that may learn to output the proper clock drift control signal based on the set of parameters of the integrated circuit device 12. For example, the machine learning model 30 may include a convolutional neural network (CNN), a graph neural network (GNN), transformers, or the like.

The training data used to train the machine learning model 30 may include the clock drift control signal as determined based on any suitable synchronization method (e.g., as implemented by the remote-source correction 24) and a set of parameters of the integrated circuit device 12 at the time the clock drift control signal was determined. The set of parameters may include any one or more parameters of the integrated circuit device and may be any suitable determinable (e.g., measurable, estimable, recorded) aspect(s) of the integrated circuit device 12 at the time that the drift control signal is properly determined based on a remote time input signal. In one example, the set of parameters may include any information affecting the behavior of the LO 14 or the frequency or phase control circuitry 16. For example, the board management controller 26 may maintain a component information record 32 with information about the components of the integrated circuit device 12, including aspects of the LO 14 or the frequency or phase control circuitry 16. This may include a date code indicating a date of manufacture of the component, a manufacturer of the component, a specified supply voltage of the component, and so forth. Based on the time and date from the TOD register 28 and the component information record 32, the processing circuitry 18 may determine an age of the LO 14, an age of the frequency or phase control circuitry 16, or other characteristics of these components that may be part of the set of parameters used in the training data to train the machine learning model 30. For example, the set of parameters that may be determined may include a present powered-on time representing the amount of time that the integrated circuit device 12 has been in a powered-on state since the most recent power-on or a lifetime powered-on time representing the sum of all powered-on time during the lifetime of the integrated circuit device 12. Additionally or alternatively, the TOD register 28 and/or the component information record 32 may be located in other memory or storage separate from the board management controller 26.

The set of parameters of the integrated circuit device 12 may also include any sensed data relating to a state of the integrated circuit 12. Thus, the integrated circuit 12 may include any suitable sensors 34 or may interface with sensors 34 external to the integrated circuit 12 that may provide feedback about the integrated circuit 12 (e.g., via input-out (I/O) or network connections). For example, a voltage sensor 36 may measure a supply voltage that may be provided to the LO 14 or the frequency or phase control circuitry 16. A temperature sensor 38 may measure a temperature of the integrated circuit device 12 (e.g., a temperature of the LO 14, a temperature of the frequency or phase control circuitry 16, a temperature of other components of the integrated circuit device 12). A motion sensor 40 may detect movement of the integrated circuit device 12 (e.g., an inertial measurement sensor such as a gyroscopic sensor, a magnetometer that may detect orientation changes), which may include a vibration, a frequency, or magnitude of motion. A geographic sensor 42 may record a present geographic location and an altitude sensor 44 may detect an altitude of the integrated circuit device 12, since the geographic placement of the integrated circuit device may affect the components involved in clock generation (e.g., via cosmic radiation, magnetic fields). Additionally or alternatively, the training data may include feedback from the machine learning model itself (e.g., a synthesized version of the clock drift control signal from the machine learning model may be compared to the clock drift control signal from the remote-source correction).

In some cases, the machine learning model 30 may be trained using the set of parameters in the manufacture of the integrated circuit device 12 instead of, or in addition to, training the machine learning model 30 during normal operation in the field. For example, the set of parameters may be made to vary in a manufacturing environment, causing the system clock signals to drift based on the way the set of parameters affects the operation of the LO 14 and the frequency or phase control circuitry 16. For example, the integrated circuit device 12 may be heated so that the temperature of the integrated circuit device 12 is swept across a variety of possible values. At the same time or another time, other parameters of the set of parameters, such as the supply voltage to the LO 14 or frequency or phase control circuitry 16, may be swept across a variety of possible values. An appropriate clock drift control signal based on the remote input time signal may be determined and used to train the machine learning model 30 while the set of parameters (or a subset of the set of parameters) is being controlled.

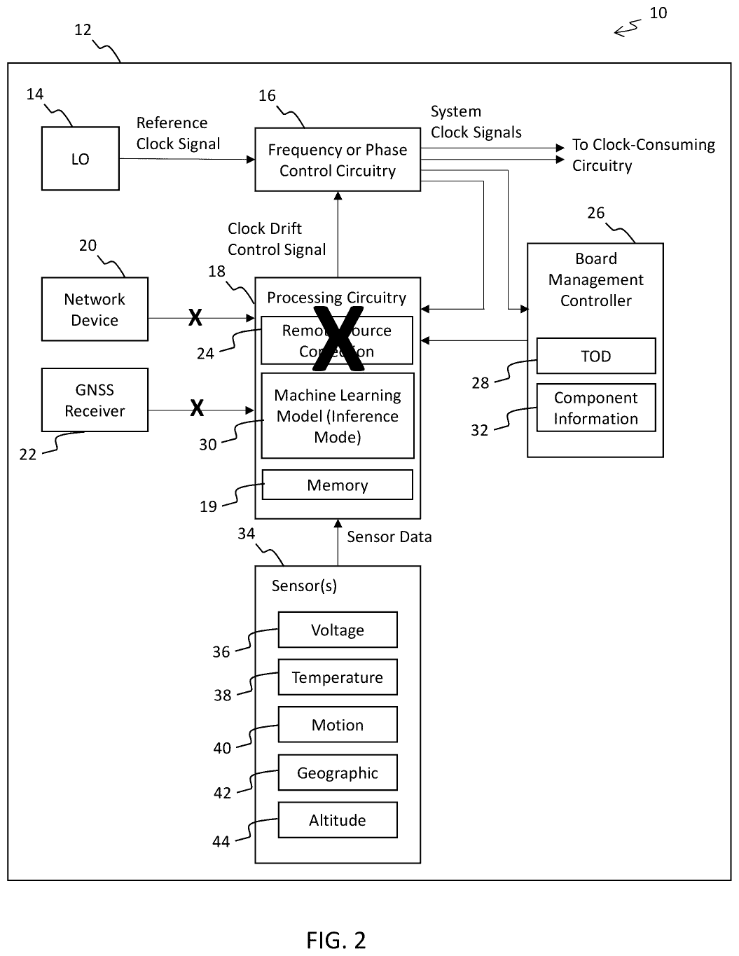

In either case, when the remote input time signal is unavailable and the machine learning model 30 has been trained, the machine learning model 30 may operate in an inference mode to generate a synthetic clock drift control signal that approximates an equivalent clock drift control signal that would be generated based on the remote input time signal (e.g., PTP signal, 1PPS signal). An example of such operation is shown in FIG. 2, in which the clock drift control system 10 operates in a holdover mode in the absence of a remote input time signal (e.g., PTP signal, 1PPS signal). The remote input time signal may be absent for any number of possible reasons. The remote input time signal may be too weak to detect, the integrated circuit device 12 may become disconnected from a network providing the remote input time signal, or the network itself may become unavailable, to name a few examples. Moreover, in some embodiments, the network device 20 or the GNSS receiver 22 may not be present in or connected to the integrated circuit device 12, and the processing circuitry 18 may always operate in a holdover mode, using the previously trained machine learning model 30 (e.g., as trained during the manufacturing process). In any case, without the remote time input signal, the remote-source correction 24 may be unavailable to generate the clock drift control signal, and thus the trained machine learning model 30 may be used to synthesize the clock drift control signal in the absence of the remote time input signal.

In the holdover mode, the clock drift control system 10 shown in FIG. 2 may use the trained machine learning model 30 to generate the synthetic clock drift control signal based on the set of parameters of the integrated circuit device 12 that were used to train the machine learning model 30. The processing circuitry 18 may receive the set of parameters from the board management controller 26 and/or the sensors 34. In some cases, a different set of parameters of the integrated circuit device 12 may be available than were used to train the machine learning model 30. The machine learning model 30 may synthesize the clock drift control signal based on the set of parameters that are available, though the resulting clock drift control signal may be less accurate or less precise. In addition to the synthetic clock drift control signal generated by the trained machine learning model 30, in some embodiments, the processing circuitry 18 may also generate a second synthetic clock drift control signal using on a physics-based model (e.g., an equation, such as a polynomial function; a table) that uses the same or a different set of parameters.

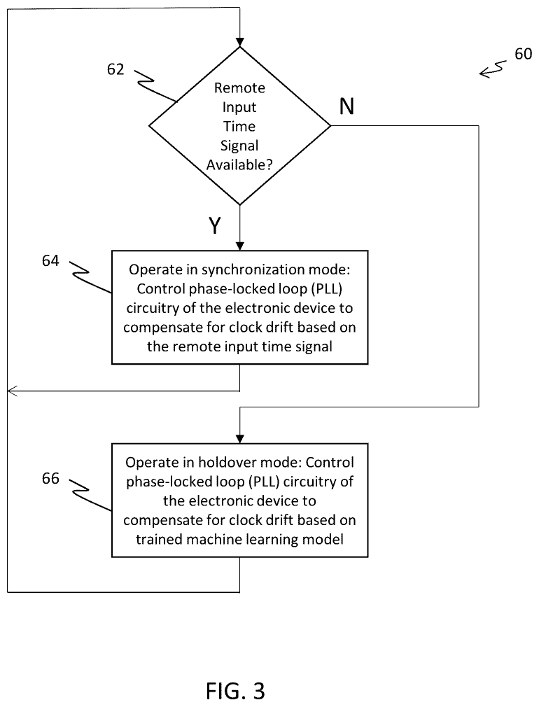

FIG. 3 illustrates a flowchart 60 of a method for operating the clock drift control system 10 of FIGS. 1 and 2. If a remote input time signal (e.g., PTP signal, 1PPS signal) is available (decision block 62), the clock drift control system may operate in a synchronization mode (block 64). In the synchronization mode, the processing circuitry of the clock drift control system may control frequency or phase control circuitry (e.g., phase-locked loop (PLL) circuitry) of the integrated circuit device to compensate for clock drift based on the remote input time signal. If a remote input time signal (e.g., PTP signal, 1PPS signal) is not available (decision block 62), the clock drift control system may operate in a holdover mode (block 66). In the holdover mode, the processing circuitry of the clock drift control system may control frequency or phase control circuitry (e.g., phase-locked loop (PLL) circuitry) of the integrated circuit device to compensate for clock drift based on the trained machine learning model.

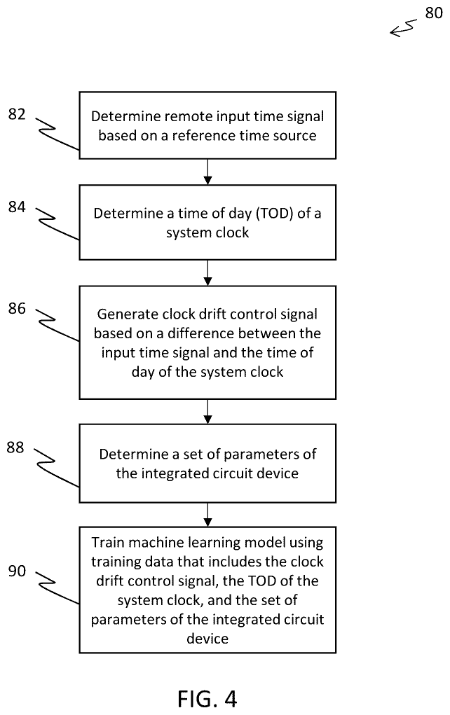

To train the machine learning model, as illustrated by a flowchart 80 of FIG. 4, the processing circuitry of the integrated circuit device may determine a remote input time signal that is based on a reference time source (block 82). The processing circuitry of the integrated circuit device may determine a time of day (TOD) of a system clock of the integrated circuit device (block 84). Based on the difference between the remote input time signal and the TOD of the system clock, the processing circuitry may generate a clock drift control signal (block 86). Meanwhile, the processing circuitry may determine a contemporaneous set of parameters of the integrated circuit device (block 88). As mentioned above, this may include any suitable information relating to a state of the integrated circuit device that may affect the generation of the system clock signals (e.g., the operation of the local oscillator (LO) and/or a phase-locked loop (PLL)). The processing circuitry may train a machine learning model using training data that includes the clock drift control signal, the TOD of the system clock, and the set of parameters of the integrated circuit device (block 90).

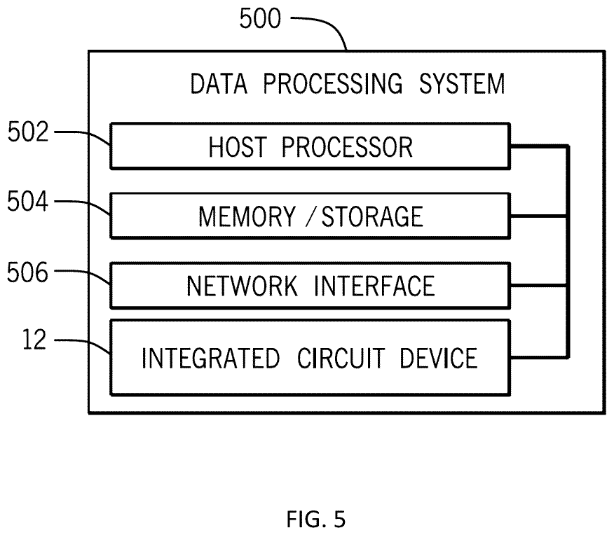

An integrated circuit device including the clock drift control system of this disclosure may represent or be part of a data processing system, such as a data processing system 500, shown in FIG. 5. The data processing system 500 may include the integrated circuit device 12 (e.g., a programmable logic device, an ASIC, a processor), a host processor 502, memory and/or storage circuitry 504, or a network interface 506. The clock drift control system of this disclosure may be part of the integrated circuit system 12 (e.g., a programmable logic device), the host processor 502, the memory and/or storage circuitry 504, or the network interface 506, or another integrated circuit such as a graphics processing unit (GPU) or AI application specific integrated circuit (ASIC). The data processing system 500 may include more or fewer components (e.g., electronic display, user interface structures, application specific integrated circuits (ASICs)). The host processor 502 may include any processors that may manage a data processing request for the data processing system 500 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 504 may include random access memory (RAM), read-only memory (ROM), one or more hard drives, flash memory, or the like. The memory and/or storage circuitry 504 may hold data to be processed by the data processing system 500. In some cases, the memory and/or storage circuitry 504 may also store configuration programs (e.g., bitstreams, mapping function) for programming the integrated circuit device 12. The network interface 506 may allow the data processing system 500 to communicate with other electronic devices. The data processing system 500 may include several different packages or may be contained within a single package on a single package substrate. For example, components of the data processing system 500 may be located on several different packages at one location (e.g., a data center) or multiple locations. For instance, components of the data processing system 500 may be located in separate geographic locations or areas, such as different cities, states, or countries.

The data processing system 500 may be part of a data center that processes a variety of different requests. For instance, the data processing system 500 may receive a data processing request via the network interface 506 to perform encryption, decryption, machine learning, video processing, voice recognition, image recognition, data compression, database search ranking, bioinformatics, network security pattern identification, spatial navigation, digital signal processing, or other specialized tasks.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112 (f). However, for any claims containing elements designated in any other manner, it is intended that such elements are not to be interpreted under 35 U.S.C. 112 (f).

### EXAMPLE EMBODIMENTS

### Example Embodiment 1. A system comprising:

a phase-locked loop to provide a system clock signal based on a reference clock signal and a drift control signal; and
processing circuitry to generate the drift control signal based on a trained machine learning model.

Example Embodiment 2. The system of example embodiment 1, comprising a sensor to measure a parameter of the system, wherein the trained machine learning model is trained at least during the synchronization mode based at least on the parameter of the system and the input time reference signal.

Example Embodiment 3. The system of example embodiment 2, wherein the sensor comprises a voltage sensor and the parameter comprises a voltage level.

Example Embodiment 4. The system of example embodiment 2, wherein the sensor comprises a temperature sensor and the parameter comprises a temperature.

Example Embodiment 5. The system of example embodiment 2, wherein the sensor comprises an inertial sensor and the parameter comprises a motion of the system.

Example Embodiment 6. The system of example embodiment 2, wherein the sensor comprises a geographic location sensor and the parameter comprises a geographic location.

Example Embodiment 7. The system of example embodiment 2, wherein the sensor comprises an altitude sensor and the parameter comprises an altitude.

Example Embodiment 8. The system of example embodiment 1, comprising a time of day clock to track a time of day of the system, wherein the trained machine learning model is trained based at least on the time of day of the system and the input time reference signal.

Example Embodiment 9. The system of example embodiment 1, wherein the processing circuitry is to determine an age of a local oscillator providing the reference clock, wherein the trained machine learning model is trained based at least on the age of the local oscillator and the input time reference signal.

Example Embodiment 10. The system of example embodiment 1, wherein the processing circuitry is to determine a lifetime powered-on time of the system, wherein the trained machine learning model is trained based at least on the lifetime powered-on time of the system and the input time reference signal.

Example Embodiment 11. The system of example embodiment 1, wherein the processing circuitry is to determine a present powered-on time since the most recent time the system was powered on, wherein the trained machine learning model is trained based at least on the present powered-on time and the input time reference signal.

Example Embodiment 12. A method comprising:
determining an input time signal based on a reference time source;
determining a time of day of a system clock of an integrated circuit device based on a system clock signal;
generating a clock drift control signal based on a difference between the input time signal and the time of day of the system clock, wherein the clock drift control signal is to control frequency or phase control circuitry to generate the system clock signal;
determining a set of parameters of the integrated circuit device; and
training a machine learning model to be able to generate the clock drift control signal when the input time signal is unavailable, wherein the machine learning model is trained using training data comprising:
the clock drift control signal generated based on the difference between the input time signal and the time of day of the system clock;
the time of day of the system clock; and
the set of parameters of the integrated circuit device.

Example Embodiment 13. The method of example embodiment 12, wherein the set of parameters of the integrated circuit device comprises an age of a local oscillator of the integrated circuit device, a present powered-on time since the most recent time the integrated circuit device was powered on, a lifetime powered-on time of the integrated circuit device, a motion of the integrated circuit device, an age of the frequency or phase control circuitry, a temperature of the integrated circuit device, a supply voltage of the integrated circuit device, a geographic location of the integrated circuit device, or an altitude of the integrated circuit device, or any combination thereof.

Example Embodiment 14. The method of example embodiment 12, wherein the set of parameters of the integrated circuit device comprises a single parameter of the integrated circuit device.

Example Embodiment 15. The method of example embodiment 12, comprising:
determining that the input time signal is unavailable; and
based on the input time signal being unavailable, generating the clock drift control signal based on the trained machine learning model using the time of day of the system clock and the set of parameters of the integrated circuit device.

Example Embodiment 16. The method of example embodiment 12, wherein the method is performed during normal operation of the integrated circuit device.

Example Embodiment 17. The method of example embodiment 12, wherein the method is performed during manufacturing of the integrated circuit device.

Example Embodiment 18. An article of manufacture comprising one or more tangible, non-transitory, machine-readable media comprising instructions that, when executed by processing circuitry of an integrated circuit device, result in operations comprising:
in a synchronization mode in which a remote input time signal is available, controlling phase-locked loop circuitry of the integrated circuit device to compensate for clock drift based on the remote input time signal; and
in a holdover mode in which the remote input time signal is unavailable, controlling phase-locked loop circuitry of the integrated circuit device to compensate for the clock drift based on a trained machine learning model trained during the synchronization mode.

Example Embodiment 19. The article of manufacture of example embodiment 18, wherein, in the holdover mode, controlling the phase-locked loop circuitry of the integrated circuit device to compensate for the clock drift based on the trained machine learning model comprises:
determining a set of parameters of the integrated circuit device; and
generating a clock drift signal using the trained machine learning model based on the set of parameters of the integrated circuit device.

Example Embodiment 20. The article of manufacture of example embodiment 19, wherein the set of parameters of the integrated circuit device comprises:
an age of a local oscillator of the integrated circuit device;
a present powered-on time of the integrated circuit device since the start of the most recent power-on;
a lifetime powered-on time of the integrated circuit device;
a motion of the integrated circuit device;
a temperature of the integrated circuit device;
an age of the frequency or phase control circuitry;
a supply voltage of the integrated circuit device;
a geographic location of the integrated circuit device; or
an altitude of the integrated circuit device; or
any combination thereof.

What is claimed is:

1. A system comprising:
a phase-locked loop to provide a system clock signal based on a reference clock signal and a drift control signal; and
processing circuitry to generate the drift control signal based on a trained machine learning model.

2. The system of claim 1, comprising a sensor to measure a parameter of the system, wherein the trained machine learning model is trained at least during the synchronization mode based at least on the parameter of the system and the input time reference signal.

3. The system of claim 2, wherein the sensor comprises a voltage sensor and the parameter comprises a voltage level.

4. The system of claim 2, wherein the sensor comprises a temperature sensor and the parameter comprises a temperature.

5. The system of claim 2, wherein the sensor comprises an inertial sensor and the parameter comprises a motion of the system.

6. The system of claim 2, wherein the sensor comprises a geographic location sensor and the parameter comprises a geographic location.

7. The system of claim 2, wherein the sensor comprises an altitude sensor and the parameter comprises an altitude.

8. The system of claim 1, comprising a time of day clock to track a time of day of the system, wherein the trained machine learning model is trained based at least on the time of day of the system and the input time reference signal.

9. The system of claim 1, wherein the processing circuitry is to determine an age of a local oscillator providing the reference clock signal, wherein the trained machine learning model is trained based at least on the age of the local oscillator and the input time reference signal.

10. The system of claim 1, wherein the processing circuitry is to determine a lifetime powered-on time of the system, wherein the trained machine learning model is trained based at least on the lifetime powered-on time of the system and the input time reference signal.

11. The system of claim 1, wherein the processing circuitry is to determine a present powered-on time since the most recent time the system was powered on, wherein the trained machine learning model is trained based at least on the present powered-on time and the input time reference signal.

12. A method comprising:
determining an input time signal based on a reference time source;
determining a time of day of a system clock of an integrated circuit device based on a system clock signal;
generating a clock drift control signal based on a difference between the input time signal and the time of day of the system clock, wherein the clock drift control signal is to control frequency or phase control circuitry to generate the system clock signal;
determining a set of parameters of the integrated circuit device; and
training a machine learning model to be able to generate the clock drift control signal when the input time signal is unavailable, wherein the machine learning model is trained using training data comprising:
the clock drift control signal generated based on the difference between the input time signal and the time of day of the system clock;
the time of day of the system clock; and
the set of parameters of the integrated circuit device.

13. The method of claim 12, wherein the set of parameters of the integrated circuit device comprises an age of a local oscillator of the integrated circuit device, a present powered-on time since the most recent time the integrated circuit device was powered on, a lifetime powered-on time of the integrated circuit device, a motion of the integrated circuit device, an age of the frequency or phase control circuitry, a temperature of the integrated circuit device, a supply voltage of the integrated circuit device, a geographic location of the integrated circuit device, or an altitude of the integrated circuit device, or any combination thereof.

14. The method of claim 12, wherein the set of parameters of the integrated circuit device comprises a single parameter of the integrated circuit device.

15. The method of claim 12, comprising:
determining that the input time signal is unavailable; and
based on the input time signal being unavailable, generating the clock drift control signal based on the trained machine learning model using the time of day of the system clock and the set of parameters of the integrated circuit device.

16. The method of claim 12, wherein the method is performed during normal operation of the integrated circuit device.

17. The method of claim 12, wherein the method is performed during manufacturing of the integrated circuit device.

18. An article of manufacture comprising one or more tangible, non-transitory, machine-readable media comprising instructions that, when executed by processing circuitry of an integrated circuit device, result in operations comprising:
in a synchronization mode in which a remote input time signal is available, controlling phase-locked loop circuitry of the integrated circuit device to compensate for clock drift based on the remote input time signal; and
in a holdover mode in which the remote input time signal is unavailable, controlling phase-locked loop circuitry of the integrated circuit device to compensate for the clock drift based on a trained machine learning model trained during the synchronization mode.

19. The article of manufacture of claim 18, wherein, in the holdover mode, controlling the phase-locked loop circuitry of the integrated circuit device to compensate for the clock drift based on the trained machine learning model comprises:
determining a set of parameters of the integrated circuit device; and
generating a clock drift signal using the trained machine learning model based on the set of parameters of the integrated circuit device.

20. The article of manufacture of claim 19, wherein the set of parameters of the integrated circuit device comprises:
an age of a local oscillator of the integrated circuit device;
a present powered-on time of the integrated circuit device since the start of the most recent power-on;
a lifetime powered-on time of the integrated circuit device;
a motion of the integrated circuit device;
a temperature of the integrated circuit device;
an age of the frequency or phase control circuitry;
a supply voltage of the integrated circuit device;
a geographic location of the integrated circuit device; or
an altitude of the integrated circuit device; or
any combination thereof.
